(19) United States
(12) Patent Application Publication
(10) Pub. No.: US 2026/0293644 A1
(43) Pub. Date: Sep. 24, 2026

(54) Diffusion Barrier For Metal/Semiconductor Components

(71) Applicants: Government of the United States, as represented by the Secretary of the Air Force, Wright-Patterson AFB, OH (US); WRIGHT STATE UNIVERSITY, Dayton, OH (US)

(72) Inventors: Weisong WANG, Dayton, OH (US); Ahmad ISLAM, Beavercreek, OH (US); Kevin D. LEEDY, Dayton, OH (US)

(21) Appl. No.: 19/056,139

(22) Filed: Feb. 18, 2025

Related U.S. Application Data
(60) Provisional application No. 63/554,974, filed on Feb. 17, 2024.

(51) Int. Cl. H10W 20/41; H10D 1/66; H10D 30/47; H10D 30/60

(52) U.S. Cl. CPC H10W 20/425; H10D 1/66; H10D 30/471; H10D 30/60

(57) ABSTRACT

Diffusion barriers for metal/semiconductor components are disclosed including tungsten nitride, tantalum nitride, ruthenium nitride, hexagonal boron nitride, or combinations thereof. Metal oxide semiconductor capacitors are disclosed having a diffusion barrier at the metal/dielectric layer interface. Metal oxide semiconductor field-effect transistors are disclosed including a gate having an exterior including at least one gate contact, and a gate contact pad, wherein the exterior, other than the at least one gate contact, is encompassed by the diffusion barrier. GaN high electron mobility transistors are disclosed including a gate having the diffusion barrier at the metal/semiconductor interface. Methods of making and using same are further disclosed.

### RELATED APPLICATION

This application claims the benefit of and priority to U.S. Prov. App. No. 63/554,974, filed Feb. 17, 2024, entitled “Diffusion Barrier for Metal/Dielectric Interface,” which is hereby incorporated by reference in its entirety.

### RIGHTS OF THE GOVERNMENT

This invention was made with government support under FA8075-18-D-0015 awarded by the Department of Defense. The government has certain rights in the invention. The invention described herein may be manufactured and used by or for the Government of the United States for all governmental purposes without the payment of any royalty.

### FIELD OF THE INVENTION

The present invention relates to diffusion barriers for metal/semiconductor components, including metal/dielectric interfaces and direct metal/semiconductor interfaces, as well as methods of making and using same.

### BACKGROUND OF THE INVENTION

High temperature (“HT”) applications (e.g, deep gas/oil drilling, hypersonic vehicles, space exploration, electric vehicles, or gas turbines) will benefit from the development of electronics that operate over a wide temperature range. These HT electronics require use of wider bandgap materials such as SiC, GaN, and β-Ga₂O₃ as semiconductors for meeting the digital, radio frequency (“RF”) and power switching needs, respectively.

Known metal/dielectric, dielectric/semiconductor, and metal/semiconductor interfaces do not provide abrupt metal/dielectric, dielectric/semiconductor, or metal/semiconductor interfaces that operate above 500° C.

There is a need for abrupt metal/dielectric, dielectric/semiconductor, and metal/semiconductor interfaces to operate above 500° C. Such abruptness ensures negligible diffusion of materials across any interfaces. Thus, the present invention includes diffusion barriers for metal/dielectric and metal/semiconductor interfaces having the required abruptness to allow operation above 500° C. and methods of making and using same. The methods of making are compatible for metal oxide semiconductor (“MOS”) device process technology and GaN high electron mobility transistor (“HEMT”) device process technology, where the devices are either processed or operated at HT and, therefore, require a diffusion barrier that may be deposited via a physical vapor deposition process and also ensures an abrupt metal/dielectric or metal/semiconductor interface with negligible diffusion of metals into the dielectric, dielectric into the metal, metal into the semiconductor, and semiconductor into the metal.

### BRIEF DESCRIPTION OF THE INVENTION

The present invention relates to diffusion barriers for metal/semiconductor components having metal/dielectric interfaces and direct metal/semiconductor interfaces, as well as methods of making and using same, particularly diffusion barriers having the required abruptness to allow operation at temperatures of 500° C. or greater. The process is compatible for MOS device process technology, where the devices are either processed or operated at HT, and which therefore require a diffusion barrier that may be deposited via a physical vapor deposition process and may also ensure an abrupt metal/dielectric interface or metal/semiconductor interface with negligible diffusion of metals into the dielectric and dielectric into the metal, or negligible diffusion of metals into the semiconductor and semiconductor into the metal.

In one exemplary embodiment, a diffusion barrier includes tungsten nitride, tantalum nitride, ruthenium nitride, hexagonal boron nitride, or combinations thereof.

Further aspects of the subject matter of the present disclosure are provided by the following clauses:

The diffusion barrier of any preceding clause, wherein the diffusion barrier includes the tungsten nitride and has a total atomic percentage of nitrogen of from about 0.5% to about 4%.

The diffusion barrier of any preceding clause, wherein the diffusion barrier has a total atomic percentage nitrogen of from about 1.5% to about 2%.

The diffusion barrier of any preceding clause, wherein the diffusion barrier includes the tungsten nitride, and the tungsten nitride is selected from the group consisting of W_{4.6}N₄, W_{2.56}N₄, W_{7.08}N₆, W₂N, amorphous tungsten nitride, α-W, and combinations thereof.

The diffusion barrier of any preceding clause, wherein the diffusion barrier includes a mixture of W_{4.6}N₄, W_{2.56}N₄, and W_{7.08}N₆.

The diffusion barrier of any preceding clause, wherein the diffusion barrier includes the tantalum nitride, and the tantalum nitride is selected from the group consisting of TaN_{0.1}, Ta₂N, amorphous tantalum nitride, β-Ta, and combinations thereof.

The diffusion barrier of any preceding clause, wherein the diffusion barrier includes the ruthenium nitride.

The diffusion barrier of any preceding clause, wherein the diffusion barrier includes the hexagonal boron nitride.

A metal oxide semiconductor capacitor, comprising a first metal layer, the diffusion barrier of any preceding clause, and a dielectric layer.

The metal oxide semiconductor capacitor of any preceding clause, wherein the first metal layer has a first metal layer top and a first metal layer bottom, the diffusion barrier has a diffusion barrier top and a diffusion barrier bottom, the dielectric layer has a dielectric layer top and a dielectric layer bottom, the metal oxide semiconductor capacitor further includes a semiconductor substrate layer having a semiconductor substrate layer top and a semiconductor substrate layer bottom, the metal oxide semiconductor capacitor further includes a second metal layer having a second metal layer top and a second metal layer bottom, the diffusion barrier top is in contact with the first metal layer bottom, the dielectric layer top is in contact with the diffusion barrier bottom, the semiconductor substrate layer top is in contact with the dielectric layer bottom, and the second metal layer top is in contact with the semiconductor substrate layer bottom.

The metal oxide semiconductor capacitor of any preceding clause, wherein the first metal layer includes a first metal sublayer having a first metal sublayer top and a first metal sublayer bottom, the first metal sublayer including at least one of Pt or Au, the first metal layer further includes a second metal sublayer having a second metal sublayer top and a second metal sublayer bottom, the second metal sublayer including at least one of Ti, Pt or Au, the second metal sublayer top is in contact with the first metal sublayer bottom, the first metal layer further includes a third metal sublayer having a third metal sublayer top and a third metal sublayer bottom, the third metal sublayer including at least one of Ti or Ni, the third metal sublayer top is in contact with the second metal sublayer bottom, the third metal sublayer bottom is in contact with the diffusion barrier top, the dielectric layer includes SiO₂, the semiconductor layer includes at least one of Si or β-Ga₂O₃ as the semiconductor, and the second metal layer includes an alloy of Ti and Au or an alloy of Ti, Al, Ni, and Au, the second metal layer allowing diffusion of metal atoms into the semiconductor layer.

The metal oxide semiconductor capacitor of any preceding clause, wherein the first metal layer includes an alloy of Pt and Au or an alloy of Ti and at least one of Pt or Au, the dielectric layer comprises SiO₂, the semiconductor layer comprises at least one of Si or β-Ga₂O₃, and the second metal layer comprises an alloy of Ti and Au or an alloy of Ti, Al, Ni and Au, the second metal layer allowing diffusion of metal atoms into the semiconductor layer.

A semiconductor transistor, comprising a gate and the diffusion barrier of any preceding clause.

The semiconductor transistor of any preceding clause, wherein the semiconductor transistor is a metal oxide semiconductor field-effect transistor, including the gate having an exterior, the exterior including at least one gate contact and a gate contact pad, wherein the exterior, other than the at least one gate contact, is encompassed by the diffusion barrier of any preceding clause.

The metal oxide semiconductor field-effect transistor of any preceding clause, further including a source contact having a first source contact layer, a second source contact layer, and a third source contact layer, a source contact pad having a single layer, a drain contact having a first drain contact layer, a second drain contact layer, and a third drain contact layer, a drain contact pad having a single layer, a dielectric, a semiconductor, a passivation everywhere on the metal oxide semiconductor field-effect transistor except on the source contact pad, the drain contact pad, and the gate contact pad, and an insulating substrate.

The metal oxide semiconductor field-effect transistor of any preceding clause, wherein the gate contact comprises a first metal sublayer having a first metal sublayer top and a first metal sublayer bottom, the first metal sublayer comprising at least one of Pt or Au, a second metal sublayer having a second metal sublayer top and a second metal sublayer bottom, the second metal sublayer including at least one of Ti, Pt, or Au, and a third metal sublayer having a third metal sublayer top and a third metal sublayer bottom, the third metal sublayer including at least one of Ti or Ni, the second metal sublayer top being in contact with the first metal sublayer bottom, the third metal sublayer top being in contact with the second metal sublayer bottom, and the third metal sublayer bottom being in contact with the diffusion barrier top, or the gate contact comprises an alloy of Pt and Au, or an alloy of at least one of Ti, Pt, or Au, the first source contact layer and the first drain contact layer comprise Au, the second source contact layer and the second drain contact layer each independently includes an alloy of Ti and Au, or an alloy of Ti, Al, Ni, and Au, the third source contact layer and the third drain contact layer each independently includes a diffused alloy of Ti and Au, or a diffused alloy of Ti, Al, Ni and Au, the dielectric layer comprises SiO₂, and the semiconductor comprises at least one of Si or β-Ga₂O₃.

The semiconductor transistor of any preceding clause, wherein the semiconductor transistor is a GaN high electron mobility transistor (HEMT), and the gate includes the diffusion barrier of and preceding clause.

The GaN HEMT of any preceding clause, wherein the GaN HEMT includes a substrate, a nucleation layer disposed over the substrate, an isolating buffer disposed over the nucleation layer, a GaN channel disposed over the isolating buffer, an AlGaN barrier disposed over the GaN channel, a GaN cap disposed over the AlGaN barrier, the gate disposed over the GaN cap such that the diffusion barrier of claim 1 is disposed immediately adjacent to the GaN cap, a metallic source; and a metallic drain.

The semiconductor transistor of any preceding clause, wherein the metal oxide semiconductor field-effect transistor has an operating temperature upper limit of at least 500° C.

An article selected from the group consisting of an aerospace vehicle, an electric powered land vehicle, a gas drilling system, an oil drilling system, a nuclear reactor, and a gas turbine comprising the diffusion barrier of any preceding clause.

The article of any preceding clause, wherein the aerospace vehicle is selected from the group consisting of a re-entry vehicle, a hypersonic missile, a hypersonic lifting body, hypersonic plane, and a hypersonic drone.

A process of making the diffusion barrier of any preceding clause, comprising depositing the diffusion barrier by physical vapor deposition.

The process of any preceding clause, wherein the physical vapor deposition includes a technique selected from the group consisting of sputtering, atomic layer deposition, electron beam evaporation, pulsed laser deposition, magnetron sputtering, and combinations thereof.

### BRIEF DESCRIPTION OF THE DRAWINGS

The accompanying drawings, which are incorporated in and constitute a part of this specification, illustrate embodiments of the present invention and, together with a general description of the invention given above and the detailed description of the embodiments given below, serve to explain the principles of the present invention.

FIG. 1 depicts a diffusion barrier 1 blocking the diffusion of metal atoms 4 into a dielectric layer 3 and blocking dielectric atoms 5 from metal 2 wherein metal atoms 4 and dielectric atoms 5 have atomic trajectory.

FIG. 2 is a schematic of an exemplary MOS capacitor (“MOSCAP”) 10 comprising a diffusion barrier 1, a top metal contact 2, a dielectric layer 3, a semiconductor 6 and a bottom metal contact 7.

FIG. 3 depicts the top-view of an example MOS field-effect transistor (“MOSFET”) 20 that comprise gate contacts 21, a gate contact pad 22, source contact pads 23, a drain contact pad 24, passivation 25, and an insulating substrate 26.

FIG. 4 depicts a cross-sectional schematic of the example MOSFET 20 of FIG. 3, where cross-section is taken along a horizontal line for any of the devices in the top or bottom lag of FIG. 3. FIG. 4 shows a diffusion barrier 1, a gate contact 21, a dielectric layer 3, a semiconductor 4, a first drain contact layer 27, a second drain contact layer 28, a third drain contact layer 29, a first source contact layer 30, a second source contact layer 31, a third source contact layer 32, passivation 25, and an insulating substrate 26. The MOSFET 20 uses diffusion barrier 1 around the gate contact 21 to block the diffusion of materials at the gate metal/dielectric interface.

FIG. 5 is a schematic of a GaN HEMT wherein the gat 19 includes a diffusion barrier 1 at the interface between the gate 19 and the semiconductor.

FIG. 6 shows the I-V curve for 2% WN SiO₂ MOSCAP at 4 mTorr in a tube furnace.

FIG. 7 shows the I-V curve for 2% WN SiO₂ MOSCAP at 4 mTorr in a rapid thermal annealing vacuum furnace.

FIG. 8 shows the I-V curve for 2% WN SiO₂ MOSCAP at 2 mTorr in a tube furnace.

FIG. 9 shows the I-V curve for 1% WN SiO₂ MOSCAP at 2 mTorr in a tube furnace.

FIG. 10 shows the I-V curve for 1% WN SiO₂ MOSCAP at 4 mTorr in a tube furnace.

FIG. 11 shows XRD scans comparing 4 mTorr deposition and 2 mTorr deposition, with a pure tungsten thin film reference.

FIG. 12 shows threshold voltages at different temperatures and different source drain voltages of a GaN HEMT according to FIG. 5. The order of all solid lines in the graphs from top to bottom is the same as labeled. The order of all broken lines in the graphs from top to bottom is the inverse as labeled for the solid lines.

FIG. 13 shows GaN HEMT characteristic curves over a range of temperatures of a GaN HEMT according to FIG. 5.

FIG. 14 shows post-high temperature data of the device following the temperature exposures of FIG. 13 for a GaN HEMT according to FIG. 5, demonstrating full recovery.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

### Definitions

Unless specifically stated otherwise, as used herein, the terms “a”, “an” and “the” mean “at least one”.

As used herein, the terms “include”, “includes” and “including” are meant to be non-limiting.

As used herein, the words “about” and “approximately” indicate a variance of up to 10% from the value being so modified. All values modified with “about” are also intended to convey the unmodified value as an alternative, so that “about 10 μm,” by way of examples, discloses both a range of 9-11 μm as well as specifically 10 μm.

As used herein, “high temperature” or “HT” indicates a temperature of at least 500° C.

Unless otherwise noted, all component or composition levels are in reference to the active portion of that component or composition, and are exclusive of impurities, for example, residual solvents or by-products, which may be present in commercially available sources of such components or compositions.

All percentages and ratios are calculated by weight unless otherwise indicated. All percentages and ratios are calculated based on the total composition unless otherwise indicated.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

### Diffusion Barrier for the Metal/Dielectric Interface or Metal/Semiconductor Interface and Articles Comprising Same

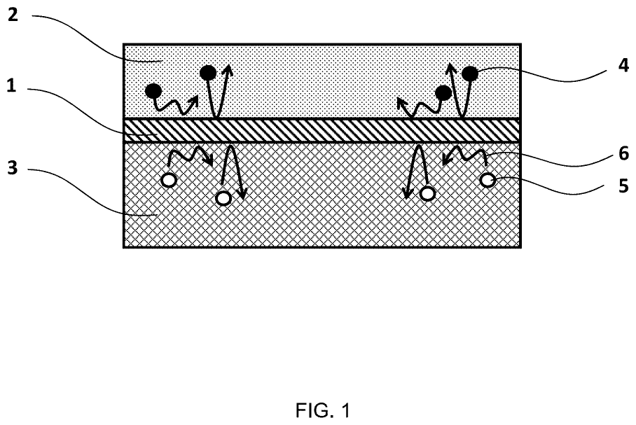

Referring to FIG. 1, in one embodiment, a diffusion barrier 1 includes tungsten nitride, tantalum nitride, ruthenium nitride, hexagonal boron nitride, or combinations thereof.

Any of the tungsten nitride, the tantalum nitride, the ruthenium nitride, the hexagonal boron nitride, alone or in combination with one another, may include any suitable nitrogen content. In one embodiment, the tungsten nitride, tantalum nitride, ruthenium nitride, hexagonal boron nitride, or combinations thereof forming the diffusion barrier has a total atomic percentage of nitrogen of from about 0.5% to about 4%, alternatively from about 0.5% to about 1.5%, alternatively from about 1.0% to about 2.0%, alternatively from about 1.5% to about 2.5%, alternatively from about 2.0% to about 3.0%, alternatively from about 2.5% to about 3.5%, alternatively from about 3.0% to about 4.0%, alternatively from about 3.5% to about 4.5%, alternatively from about 0.5% to about 1.0%, alternatively from about 1.0% to about 1.5%, alternatively from about 1.5% to about 2.0%, alternatively from about 2.0% to about 2.5%, alternatively from about 2.5% to about 3.0%, alternatively from about 3.0% to about 3.5%, alternatively from about 3.5% to about 4.0%, alternatively from about 4.0% to about 4.5%, or combinations or subranges thereof.

In one embodiment, the diffusion barrier 1 includes the tungsten nitride, alternatively consists essentially of the tungsten nitride, alternatively consists of the tungsten nitride. The tungsten nitride may have any suitable composition (on atomic basis), including, but not limited to, W_{4.6}N₄, W_{2.56}N₄, W_{7.08}N₆, W₂N, amorphous tungsten nitride, α-W, or combinations thereof. In a further embodiment, the tungsten nitride includes a mixture of W_{4.6}N₄, W_{2.56}N₄, and W_{7.08}N₆. The formulas “W_{4.6}N₄,” “W_{2.56}N₄,” “W_{7.08}N₆,” and “W₂N” are on atomic basis in all uses herein.

In one embodiment, the diffusion barrier 1 includes the tantalum nitride, alternatively consists essentially of the tantalum nitride, alternatively consists of the tantalum nitride. The tantalum nitride may have any suitable composition, including, but not limited to, TaN_{0.1}, Ta₂N, amorphous tantalum nitride, β-Ta, or combinations thereof.

In one embodiment, the diffusion barrier 1 includes the ruthenium nitride, alternatively consists essentially of the ruthenium nitride, alternatively consists of the ruthenium nitride.

In one embodiment, the diffusion barrier 1 includes the hexagonal boron nitride, alternatively consists essentially of the hexagonal boron nitride, alternatively consists of the hexagonal boron nitride.

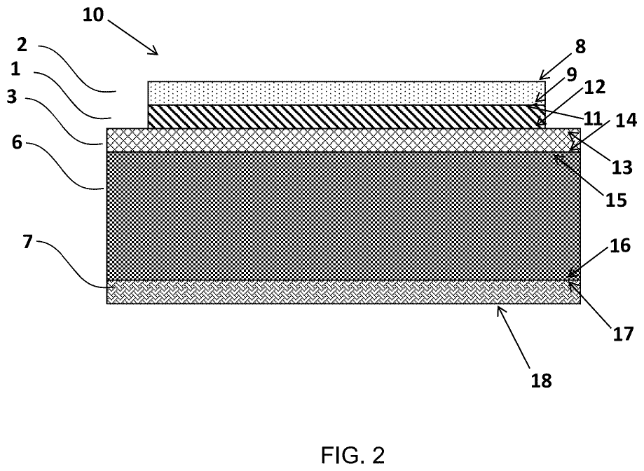

Referring to FIG. 2, in one embodiment, a metal oxide semiconductor capacitor 10 includes a first metal layer 2, the diffusion barrier 1, and a dielectric layer 3.

In a further embodiment, the metal oxide semiconductor capacitor (“MOSCAP”) 10, the first metal layer 2 has a first metal layer top 8 and a first metal layer bottom 9, the diffusion barrier 1 has a diffusion barrier top 11 and a diffusion barrier bottom 12, the dielectric layer 3 has a dielectric layer top 13 and a dielectric layer bottom 14, the metal oxide semiconductor capacitor 10 further includes a semiconductor substrate layer 6 having a semiconductor substrate layer top 15 and a semiconductor substrate layer bottom 16 and the metal oxide semiconductor capacitor 10 further includes a second metal layer 7 having a second metal layer top 17 and a second metal layer bottom 18. The diffusion barrier top 11 is in contact with the first metal layer bottom 9, the dielectric layer top 13 is in contact with the diffusion barrier bottom 12, the semiconductor substrate layer top 15 is in contact with the dielectric layer bottom 14, and the second metal layer top 17 is in contact with the semiconductor substrate layer bottom 16.

In yet a further embodiment, the first metal layer 2 includes a first metal sublayer having a first metal sublayer top and a first metal sublayer bottom, the first metal sublayer including at least one of Pt or Au and the first metal layer 2 further includes a second metal sublayer having a second metal sublayer top and a second metal sublayer bottom, the second metal sublayer including at least one of Ti, Pt or Au, wherein the second metal sublayer top is in contact with the first metal sublayer bottom. The first metal layer 2 further includes a third metal sublayer having a third metal sublayer top and a third metal sublayer bottom, the third metal sublayer including at least one of Ti or Ni, wherein the third metal sublayer top is in contact with the second metal sublayer bottom, and the third metal sublayer bottom is in contact with the diffusion barrier top.

The first metal layer 2 may have any suitable composition, including, but not limited to, a single layer refractory or non-refractory metal, a multi-layer stack of refractory or non-refractory metal or combinations thereof, at least one of Ti, Pt, Ni, or Au, an alloy of Pt and Au, an alloy of Ti and Au, an alloy of Ti and Pt, an alloy of Ti, Pt, and Au, or an alloy of Ti and Ni.

The dielectric layer 3 may have any suitable composition, including, but not limited to, SiO₂, Al₂O₃, HfO₂, or combinations thereof.

The semiconductor layer 6 may have any suitable composition, including, but not limited to, at least one of Si or β-Ga₂O₃.

The second metal layer 7 may have any suitable composition, including, but not limited to, an alloy of Ti and Au or an alloy of Ti, Al, Ni, and Au. The second metal layer 7 allows diffusion of metal atoms into the semiconductor layer 6.

In one embodiment, the first metal layer 2 includes an alloy of Pt and Au or an alloy of Ti and at least one of Pt or Au, the dielectric layer 3 includes SiO₂, the semiconductor layer 6 includes at least one of Si or β-Ga₂O₃, and the second metal layer 7 includes an alloy of Ti and Au or an alloy of Ti, Al, Ni and Au, wherein the second metal layer 7 allows diffusion of metal atoms into the semiconductor layer 6.

The metal oxide semiconductor capacitor 20 may be used to test the effectiveness of a diffusion barrier 1 placed above a dielectric layer 3 to block the diffusion of materials at the metal/dielectric interface.

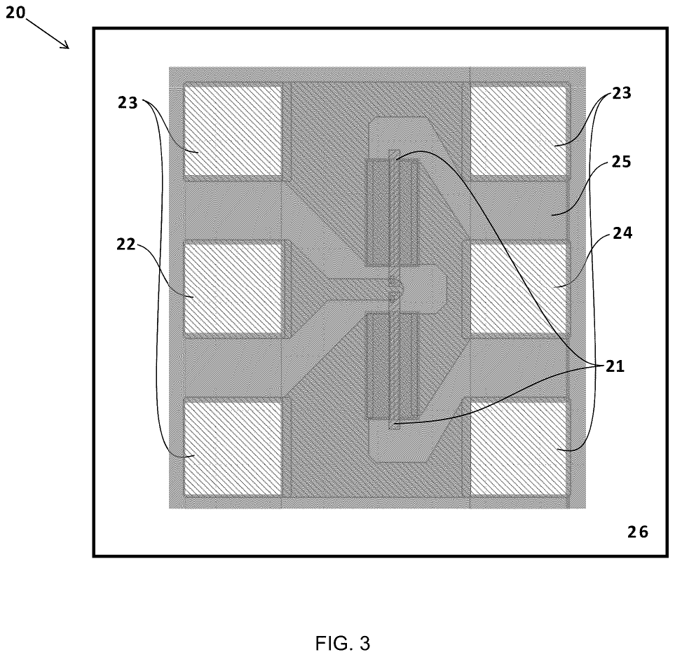

Referring to FIGS. 3-5, in one embodiment, a semiconductor transistor 20 includes a gate 19 and a diffusion barrier 1.

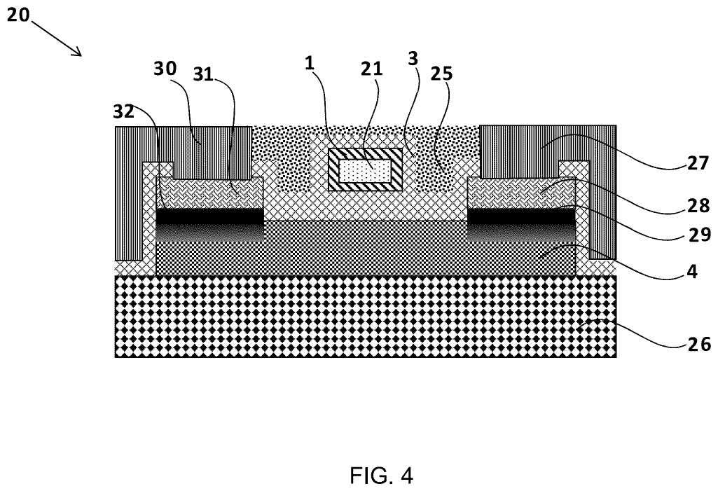

Referring to FIGS. 3 and 4, in one embodiment, a metal oxide semiconductor field-effect transistor 20 includes a gate having an exterior, the exterior including at least one gate contact 21 and a gate contact pad 22, wherein the exterior, other than the at least one gate contact 21, is encompassed by a diffusion barrier 1.

In a further embodiment, the metal oxide semiconductor field-effect transistor 20 further includes a source contact having a first source contact layer 30, a second source contact layer 31, and a third source contact layer 32, a source contact pad 23 having a single layer, a drain contact having a first drain contact layer 27, a second drain contact layer 28, and a third drain contact layer 29, a drain contact pad 24 having a single layer, a dielectric layer 3, a semiconductor 4, a passivation 25 everywhere on the metal oxide semiconductor field-effect transistor 20 except on the source contact pad 23, the drain contact pad 24, and the gate contact pad 22, and an insulating substrate 26.

The gate contact 21 may have any suitable number of sublayers, including, but not limited to, two sub-layers, three sub-layers, or more. In yet a further embodiment in which the gate contact 21 has a three-layer design, the gate contact 21 includes a first metal sublayer having a first metal sublayer top and a first metal sublayer bottom, the first metal sublayer comprising at least one of Pt or Au, a second metal sublayer having a second metal sublayer top and a second metal sublayer bottom, the second metal sublayer including at least one of Ti, Pt, or Au, and a third metal sublayer having a third metal sublayer top and a third metal sublayer bottom, the third metal sublayer including at least one of Ti or Ni. The second metal sublayer top is in contact with the first metal sublayer bottom, the third metal sublayer top is in contact with the second metal sublayer bottom, and the third metal sublayer bottom is in contact with the diffusion barrier top.

In an alternate further embodiment, the gate contact 21 includes an alloy of Pt and Au, or an alloy of at least one of Ti, Pt, or Au, the first source contact layer 30 and the first drain contact layer 27 include Au, the second source contact layer 31 and the second drain contact layer 28 each independently includes an alloy of Ti and Au or an alloy of Ti, Al, Ni, and Au, the third source contact layer 32 and the third drain contact layer 29 each independently includes a diffused alloy of Ti and Au or a diffused alloy of Ti, Al, Ni and Au, the dielectric layer 3 comprises SiO₂ and the semiconductor comprises at least one of Si or β-Ga₂O₃.

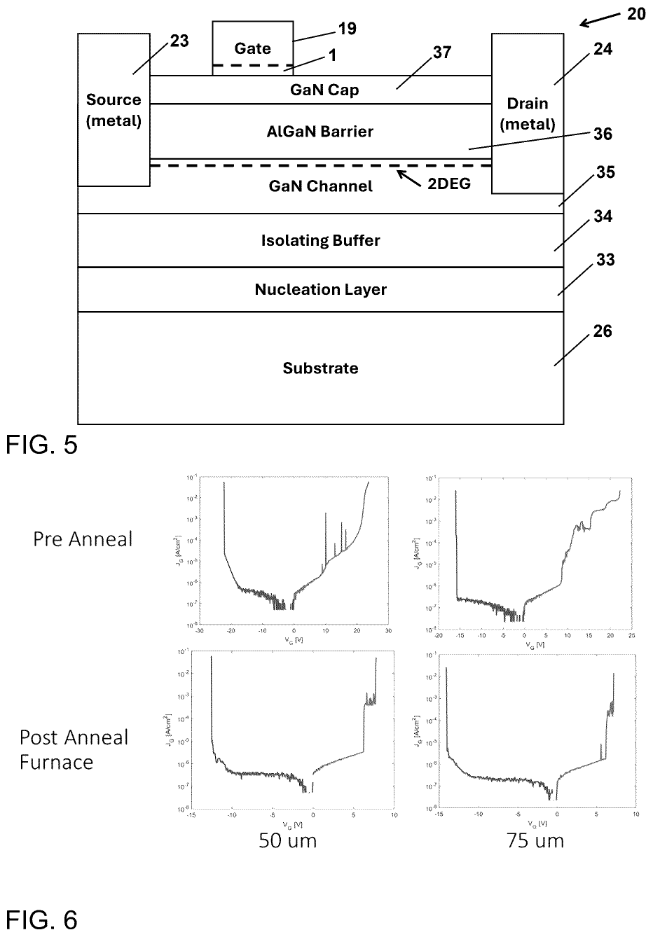

Referring to FIG. 5, in one embodiment, the semiconductor transistor 20 is a GaN HEMT 20 and the gate 19 includes the diffusion barrier 1.

In a further embodiment, the GaN HEMT transistor 20 includes a substrate 26, a nucleation layer 33 disposed over the substrate 26, an isolating buffer 34 disposed over the nucleation layer 33, a GaN channel 35 disposed over the isolating buffer 34, an AlGaN barrier 36 disposed over the GaN channel 35, a GaN cap 37 disposed over the AlGaN barrier 36, the gate 19 disposed over the GaN cap 37 such that the diffusion barrier 1 is disposed immediately adjacent to the GaN cap 37, a metallic source 23, and a metallic drain 24.

In one embodiment, the semiconductor transistor 20 has an operating temperature upper limit of at least 500° C., alternatively at least 600° C., alternatively at least 700° C., alternatively at least 800° C., alternatively at least 900° C., alternatively at least 1,000° C.

The diffusion barrier 1 may be incorporated into any suitable article, including, but not limited to, an aerospace vehicle, an electric powered land vehicle, a gas drilling system, an oil drilling system, a nuclear reactor, or a gas turbine. Suitable aerospace vehicles including, but are not limited to, a re-entry vehicle, a hypersonic missile, a hypersonic lifting body, hypersonic plane, or a hypersonic drone.

### Process of Making

The diffusion barrier 1 may be formed by any suitable process, including, but not limited to, depositing the diffusion barrier 1 by physical vapor deposition. The physical vapor deposition may include, but is not limited to, sputtering, atomic layer deposition, electron beam evaporation, pulsed laser deposition, magnetron sputtering, or combinations thereof.

### EXAMPLES

### Test Methods

X-ray diffraction (“XRD”) of the diffusion barrier was performed using a Rigaku D-MAX III thin film diffractometer with a fixed, low angle (5°) cu K_{α}□radiation source and a rotating sample holder.

Film composition of the diffusion barrier was determined with a Physical Electronics model 5700 X-ray photoelectron spectroscopy (“XPS”) system utilizing monochromatic Al Kα radiation. For XPS analysis, the photoelectron signals were obtained from the surface of the film and were used for the quantitative analysis. Attenuation of signals by surface contamination was taken into account for the analysis. The variation of line-shape between samples arises from surface oxidation of the films, which was also taken into account. The fractions of the total non-oxide tungsten and//or tantalum signals were determined. The nitrogen concentrations in the films were then obtained by calculation using Scofield cross-sections, and asymmetry parameter, analyzer transmission and atom size corrections. Then the atomic percentage of nitrogen in the film were computed.

Sheet resistance was measured using a Cascade CPS model four point probe. The probe system was connected to a Keithley 2420-C 3A Source meter for application of current and measurement of voltage. The ratio of measured voltage and applied current was used to calculate sheet resistance after consideration of probe spacing, layer thickness and correction factors.

Scanning Transmission Electron Microscopy (“STEM”) was used to reveal the effectiveness of diffusion barrier in reducing diffusion across the metal and dielectric interface. For STEM imaging, an electron transparent STEM lamella was prepared with a focused ion beam system (such as a FEI Helios Dual-beam system). The lamella may be imaged with any STEM system (such as a Hitachi HD2700, FEI Titan Themis 300) with an accelerating voltage of 200 kV or above.

Materials analysis near the diffusion barrier was performed using energy-dispersive X-ray spectroscopy (“EDX”) using, for example, a Thermo Fisher Scientific Spectra 300 S/TEM operated at 120 kV with Dual-X energy-dispersive detector and using a collection solid angle of 1.76 sr.

Materials analysis near the diffusion barrier was performed using electron energy loss spectroscopy (“EELS”) using a FEI Titan S/TEM operated, for example, at 300 kV.

Leakage properties of MOS capacitors or transistors (see FIGS. 2 and 3) was measured using Semiconductor Parametric Analyzers (such as Kiethley 4200 SCS System, Keysight B1500 or B1505 system). The change in leakage properties of the MOS capacitors or transistors before and after HT (for example, 900° C.) annealing indicated the effectiveness of the diffusion barrier (i.e. lower diffusion across the barrier causes smaller changes in leakage properties).

Capacitance of MOS capacitors or transistors (see FIGS. 2 and 3) was measured using Semiconductor Parametric Analyzers (such as Kiethley 4200 SCS System, Keysight B1500 or B1505 system) or using impedance analyzers (such as Keysight E4980 system or Keysight E4990 system). Higher diffusion across the barrier reduced the feasibility of capacitance measurement in the MOS capacitor or transistor.

### EXPERIMENTS

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

### Example 1

A diffusion barrier was made as follows: a 99.95 wt % pure tungsten target (available from Kurt J. Lesker Company) was used in a Denton Vacuum Discovery 22 DC magnetron sputtering system with a base vacuum of 3×10⁻⁷ Torr. A mass flow controller regulated the flow of argon (Ar) and nitrogen (N₂) at 198 sccm (standard cubic centimeters per minute) and 2 sccm (this composition is referred as about 1% N₂ with Ar balance (determined in part based on the gas ratio of Ar/N₂)), which resulted in an about 4×10⁻³ Torr pressure for the system during deposition. A 250 W forward radio frequency (RF) power was held constant during deposition which results in a deposition rate of 0.2 nm/s. After deposition the thickness of diffusion barrier was about 20 nm. The resulting diffusion barrier was found to have the following characteristics:
Sheet resistance of about 0.17 ohm/square was measured using 4-point probe measurement.
Microstructural analysis using XRD revealed the presence of W_{4.6}N₄, W_{2.56}N₄, and W_{7.08}N₆ in the as-deposited film.
Composition analysis using XPS revealed the presence of about 1% nitrogen (atomic basis) in the film (determined in part based on the gas ratio of Ar/N₂).
After high temperature annealing, the structure and composition of the film changed.

The resulting diffusion barrier was incorporated into a MOSCAP device. The resulting MOSCAP device had a reduction in leakage from metal towards the semiconductor (or semiconductor towards the metal) compared to prior art devices. Here, the change in leakage was tracked by measuring leakage for an as-fabricated device and a 900° C. annealed device.

The effectiveness of the diffusion barrier was also checked by measuring capacitance of the MOSCAP, where voltage was applied between the top metal contact and the semiconductor.

The semiconductor in the above example for MOSCAP was β-Ga₂O₃, the dielectric material was SiO₂, and the metal was a bilayer of 10 nm thick Pt and 200 nm thick Au.

### Example 2

A diffusion barrier was made as follows: a 99.95 wt % pure tungsten target (available from Kurt J. Lesker Company) was used in a Denton Vacuum Discovery 22 DC magnetron sputtering system with a base vacuum of 3×10⁻⁷ Torr. A mass flow controller regulated the flow of argon (Ar) and nitrogen (N₂) at 93 sccm and 2 sccm (this composition is referred as about 2.1% N₂ with Ar balance (determined in part based on the gas ratio of Ar/N₂)), which resulted in an about 4×10⁻³ Torr pressure for the system during deposition. A 250 W forward radio frequency (RF) power was held constant during deposition which resulted in a deposition rate of 0.2 nm/s. After deposition the thickness of diffusion barrier is about 20 nm. The resulting diffusion barrier was found to have the following characteristics:
Sheet resistance of about 80 ohm/square was measured using 4-point probe measurement.
Microstructural analysis using XRD revealed the presence of W_{4.6}N₄, W_{2.56}N₄ and W_{7.08}N₆ in the as-deposited film.
Composition analysis using XPS revealed the presence of about 2% nitrogen (atomic basis) in the film (determined in part based on the gas ratio of Ar/N₂).
After high temperature annealing, the structure and composition of the film changed.

The resulting diffusion barrier was incorporated into a MOSCAP device. The resulting MOSCAP device had a reduction in leakage from metal towards the semiconductor (or semiconductor towards the metal) compared to prior art devices. The change in leakage was tracked by measuring leakage for an as-fabricated device and a 900° C. annealed device.

The effectiveness of diffusion barrier was also checked by measuring capacitance of the MOSCAP, where voltage was applied between the top metal contact and the semiconductor.

The semiconductor in the above example for MOSCAP was β-Ga₂O₃, the dielectric material was SiO₂, and the metal was a bilayer of 10 nm thick Pt and 300 nm thick Au.

### Example 3

A diffusion barrier was made as follows: a 99.95 wt % pure tungsten target (available from Kurt J. Lesker Company) was used in a Denton Vacuum Discovery 22 DC magnetron sputtering system with a base vacuum of 3×10⁻⁷ Torr. A mass flow controller regulated the flow of argon (Ar) and nitrogen (N₂) at 93 sccm and 2 sccm (this composition is referred as about 2.1% N₂ with Ar balance (determined in part based on the gas ratio of Ar/N₂)), which resulted in an about 4×10⁻³ Torr pressure for the system during deposition. A 250 W forward radio frequency (RF) power was held constant during deposition which resulted in a deposition rate of 0.2 nm/s. After deposition the thickness of diffusion barrier was about 20 nm. The resulting diffusion barrier was found to have the following characteristics:
Sheet resistance of about 80 ohm/square was measured using 4-point probe measurement.
Microstructural analysis using XRD revealed the presence of W_{4.6}N₄, W_{2.56}N₄ and W_{7.08}N₆ in the as-deposited film.
Composition analysis using XPS revealed the presence of about 2% nitrogen (atomic basis) in the film (determined in part based on the gas ratio of Ar/N₂).
After high temperature annealing, the structure and composition of the film changed.

The resulting diffusion barrier was incorporated into a MOSCAP device. The resulting MOSCAP device had a reduction in leakage from metal towards the semiconductor (or semiconductor towards the metal) compared to prior art devices. The change in leakage was tracked by measuring leakage for an as-fabricated device and a 900° C. annealed device.

The effectiveness of the diffusion barrier was also checked by measuring capacitance of the MOSCAP, where voltage was applied between the top metal contact and the semiconductor.

The semiconductor in the above example for MOSCAP was Si, the dielectric material was SiO₂, and the metal was a bilayer of 10 nm thick Pt and 300 nm thick Au.

### Example 4

A diffusion barrier was made as follows: a 99.95 wt % pure tungsten target (available from Kurt J. Lesker Company) was used in a Denton Vacuum Discovery 22 DC magnetron sputtering system with a base vacuum of 3×10⁻⁷ Torr. A mass flow controller regulated the flow of argon (Ar) and nitrogen (N₂) at 198 sccm (standard cubic centimeters per minute) and 2 sccm (this composition is referred as about 1% N₂ with Ar balance (determined in part based on the gas ratio of Ar/N₂)), which resulted in an about 4×10⁻³ Torr pressure for the system during deposition. A 250 W forward radio frequency (RF) power was held constant during deposition which resulted in a deposition rate of 0.2 nm/s. After deposition the thickness of diffusion barrier was about 20 nm. The resulting diffusion barrier was found to have the following characteristics:
Sheet resistance of about 0.17 ohm/square was measured using 4-point probe measurement.
Microstructural analysis using XRD revealed the presence of W_{4.6}N₄, W_{2.56}N₄ and W_{7.08}N₆ in the as-deposited film.
Composition analysis using XPS revealed the presence of about 1% nitrogen (atomic basis) in the film (determined in part based on the gas ratio of Ar/N₂).
After high temperature annealing, the structure and composition of the film changed.

The resulting diffusion barrier was incorporated into a MOSCAP device. The resulting MOSCAP device had a reduction in leakage from metal towards the semiconductor (or semiconductor towards the metal) compared to prior art devices. The change in leakage was tracked by measuring leakage for an as-fabricated device and a 900° C. annealed device.

The effectiveness of the diffusion barrier was also checked by measuring capacitance of the MOSCAP, where voltage was applied between the top metal contact and the semiconductor.

The semiconductor in the above example for MOSCAP was Si, the dielectric material was SiO₂, and the metal was a bilayer of 10 nm thick Pt and 200 nm thick Au.

### Testing:

WNₓ was deposited by sputtering on highly doped Si and Ga₂O₃ substrates, and the dielectric material was SiO₂ to determine the quality of integration. I-V measurement was used to understand the effectiveness of diffusion barrier compared to the control sample without the diffusion barrier before and after high temperature annealing. C-V measurement was conducted to determine the dielectric constant of SiO₂ before and after annealing. The MOSCAP samples were composed of the substrate, the dielectric, the diffusion barrier, and oxide resistant top metal (a Pt/Au/Pt stack).

Each layer is obtained using a different tool. The dielectric was deposited on purchased substrates using an atomic layer deposition tool. This tool releases pulses of precursor gas which form a single layer of SiO₂ on the surface of the wafer. After several hundred pulses, the dielectric reaches several nanometers thick. The next layer, the diffusion barrier, was deposited using vacuum sputtering. Each material was tested as well as multiple deposition conditions. Finally, the top metal stack was deposited using an evaporator system.

For each MOSCAP sample, a substrate was obtained that had a SiO₂ coating. The substrate was then coated with LOR 10A photo resist as well as SPR 0.7. This photo resist was then patterned using a mask aligner and capacitor mask. Once the photo resist was exposed it was developed using MIF 300 for seventy-five seconds. Following development, each substrate was O₂ ashed for two minutes. At this point the samples were ready for diffusion barrier deposition using the Denton vacuum sputtering system. The tungsten was loaded into the Denton. Many samples were created using varying conditions. The two parameters that were varied were the nitrogen gas flow rate and deposition pressure. The nitrogen flow rate was adjusted between 0 and 2 sccm while the deposition pressure varied from 2 mTorr to 4 mTorr. Sapphire substrates were also used during WN depositions to determine the sheet resistance of the films. The sapphire substrates had the same varying deposition parameters as the MOSCAPs themselves. Once coated in the diffusion barrier, each sample was subjected to I-V tests. An untested section was then cleaved off and annealed in either the rapid thermal annealing vacuum furnace or the tube furnace. These annealed sections were then subjected to an I-V test. The results were then compared to assess the efficacy of the diffusion barrier.

After construction, each MOSCAP sample was tested using an I-V tester. This tester allows the breakdown voltage of each capacitor to be determined. A sharp jump in current through the device under test signifies a break. A small increase in current can be observed prior to this point. This breakdown occurs in both the positive and negative bias cases, but the positive bias case was of more interest. To test the temperature resistance of these MOSCAPs, they were annealed at 900° C. in a rapid thermal annealer. This device uniformly heats the sample in just a few minutes. Another tool that may be used to anneal samples is the furnace. This tool was not preferred due to the presence of oxygen in the system during the annealing process. The oxygen causes device degradation and therefore a lower breakdown voltage. Due to necessity, some samples were annealed in the furnace. Remeasuring the breakdown voltage of the capacitors post anneal provided a measure of how well the diffusion barrier works.

All deposited films were measured using 4-probe measurement for sheet resistance to determine the conductivity, as shown in Table 1.

TABLE 1
WNₓ Sheet Resistance Measurements.
WNₓ Sheet Resistance

| | 2 mTorr | 4 mTorr |
|---|---|---|
| 0% N | — | 11.21 Ω/ |
| | | sqr (4,000 Å film) |
| 1% N | 23.35 Ω/ | 39.07 Ω/ |
| | sqr (1,000 Å film) | sqr (1,000 Å film) |
| 2% N | 11.07 Ω/ | 32.99 Ω/ |
| | sqr (1,500 Å film) | sqr (1,500 Å film) |

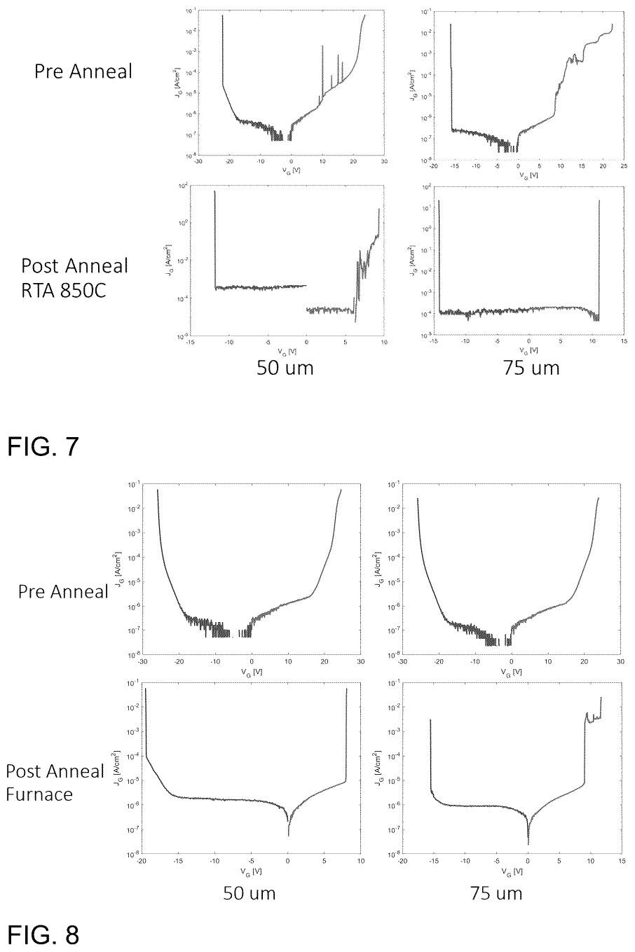

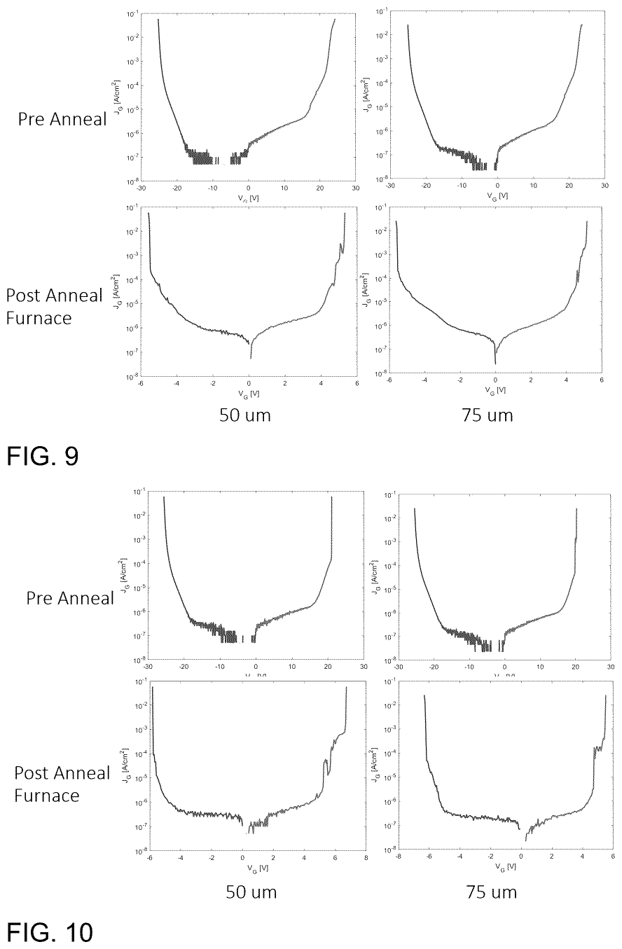

The most conductive composition/sputtering conditions were selected to continue Si MOSCAP fabrication to check the high temperature performance. The major indicator for the quality check was breakdown voltage through I-V. FIGS. 6-10 show the I-V curves for the WN MOSCAPs. Due to the rapid thermal annealing vacuum furnace equipment issues, some samples were annealed in tube furnace at 900° C. It is believed that furnace annealing may have introduced some oxidization to degrade the quality of dielectrics.

FIGS. 6-10 demonstrate the effectiveness of diffusion barrier in a MOSCAP which may be used to evaluate the effectiveness in MOSFET. The breakdown field of SiO₂ is about 10 MV/cm. FIGS. 6-10 clearly illustrate that with the incorporation of diffusion barrier the breakdown of SiO₂ maintains as expected before and after high temperature treatment.

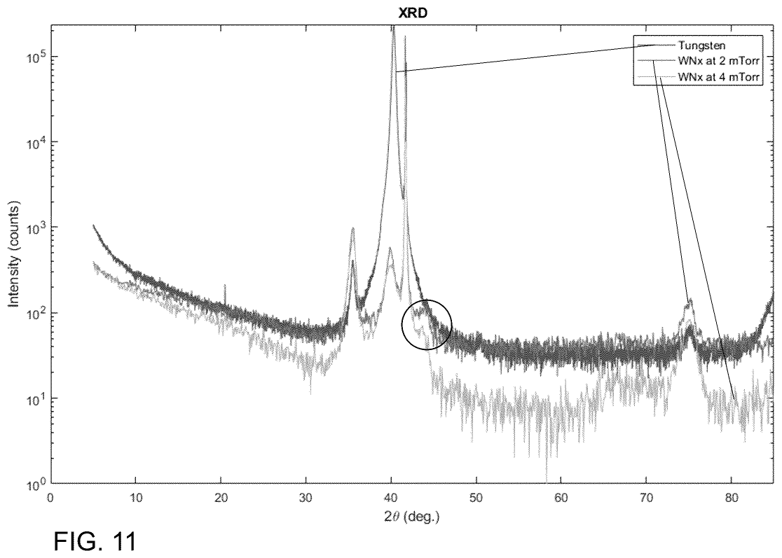

Referring to FIG. 11, the difference between 99.95 wt % pure tungsten and WNx thin films prepared as described above at different pressure (2 mTorr and 4 mTorr) is shown. The circled peak location is the indicator of the presence of low percentage of nitride incorporated in the film.

### Example 5

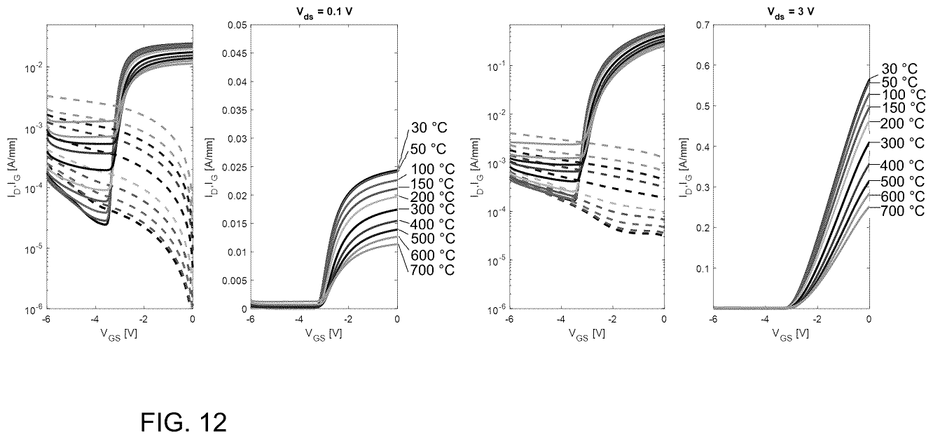

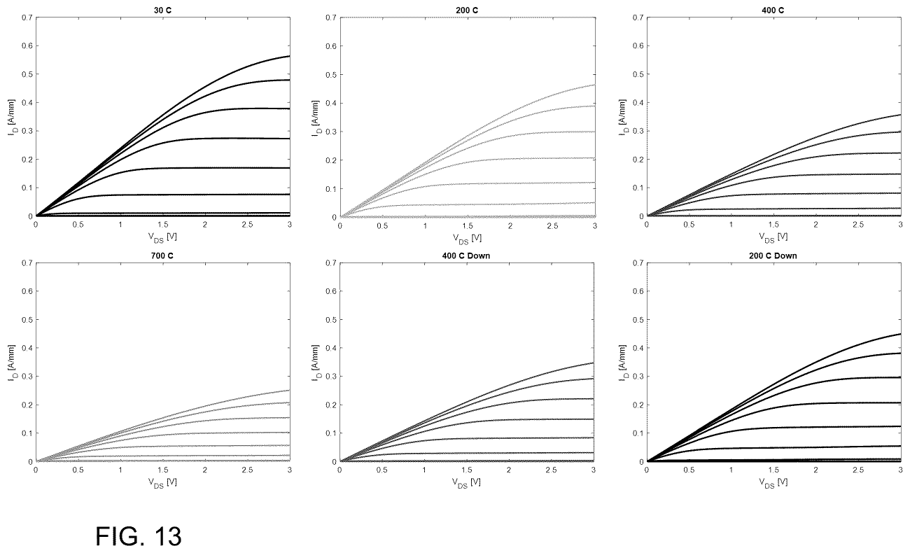

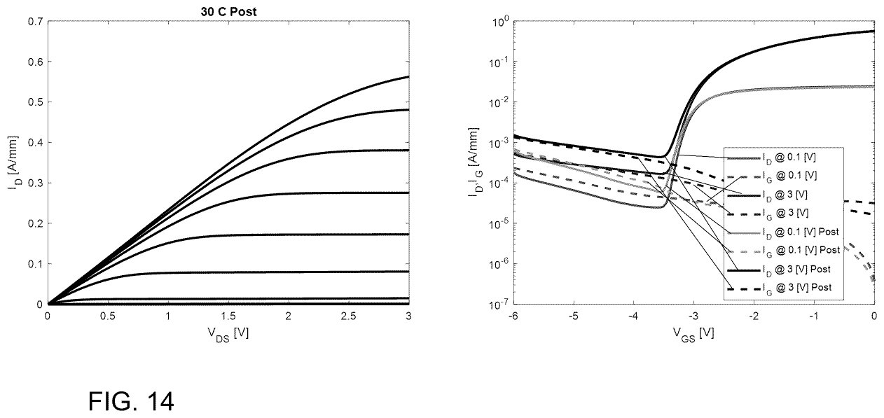

A GaN HEMT was formed according to FIG. 5, wherein the gate structure was WNₓ/Pt/Au/Pt (200 Å/100 Å/2,000 Å/300 Å). The resulting transistor functioned at all temperatures tested, from 30° C. to 700° C., as shown in FIGS. 12-14.

Every document cited herein, including any cross-referenced or related patent or application and any patent application or patent to which this application claims priority or benefit thereof, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A diffusion barrier, comprising tungsten nitride, tantalum nitride, ruthenium nitride, hexagonal boron nitride, or combinations thereof.

2. The diffusion barrier of claim 1, wherein the diffusion barrier includes the tungsten nitride and has a total atomic percentage of nitrogen of from about 0.5% to about 4%.

3. The diffusion barrier of claim 2, wherein the diffusion barrier has a total atomic percentage nitrogen of from about 1.5% to about 2%.

4. The diffusion barrier of claim 1, wherein the diffusion barrier includes the tungsten nitride, and the tungsten nitride is selected from the group consisting of W_{4.6}N₄, W_{2.56}N₄, W_{7.08}N₆, W₂N, amorphous tungsten nitride, α-W, and combinations thereof.

5. The diffusion barrier of claim 1, wherein the diffusion barrier includes a mixture of W_{4.6}N₄, W_{2.56}N₄, and W_{7.08}N₆.

6. The diffusion barrier of claim 1, wherein the diffusion barrier includes the tantalum nitride, and the tantalum nitride is selected from the group consisting of TaN_{0.1}, Ta₂N, amorphous tantalum nitride, β-Ta, and combinations thereof.

7. The diffusion barrier of claim 1, wherein the diffusion barrier includes the ruthenium nitride.

8. The diffusion barrier of claim 1, wherein the diffusion barrier includes the hexagonal boron nitride.

9. A metal oxide semiconductor capacitor, comprising a first metal layer, the diffusion barrier of claim 1, and a dielectric layer.

10. The metal oxide semiconductor capacitor of claim 9, further including wherein:
the first metal layer has a first metal layer top and a first metal layer bottom;
the diffusion barrier has a diffusion barrier top and a diffusion barrier bottom;
the dielectric layer has a dielectric layer top and a dielectric layer bottom;
the metal oxide semiconductor capacitor further includes a semiconductor substrate layer having a semiconductor substrate layer top and a semiconductor substrate layer bottom;
the metal oxide semiconductor capacitor further includes a second metal layer having a second metal layer top and a second metal layer bottom;
the diffusion barrier top is in contact with the first metal layer bottom;
the dielectric layer top is in contact with the diffusion barrier bottom;
the semiconductor substrate layer top is in contact with the dielectric layer bottom; and
the second metal layer top is in contact with the semiconductor substrate layer bottom.

11. The metal oxide semiconductor capacitor of claim 10, wherein:
the first metal layer includes a first metal sublayer having a first metal sublayer top and a first metal sublayer bottom, the first metal sublayer including at least one of Pt or Au;
the first metal layer further includes a second metal sublayer having a second metal sublayer top and a second metal sublayer bottom, the second metal sublayer including at least one of Ti, Pt or Au;
the second metal sublayer top is in contact with the first metal sublayer bottom;
the first metal layer further includes a third metal sublayer having a third metal sublayer top and a third metal sublayer bottom, the third metal sublayer including at least one of Ti or Ni;
the third metal sublayer top is in contact with the second metal sublayer bottom;
the third metal sublayer bottom is in contact with the diffusion barrier top;
the dielectric layer includes SiO₂;
the semiconductor layer includes at least one of Si or β-Ga₂O₃ as the semiconductor; and
the second metal layer includes an alloy of Ti and Au or an alloy of Ti, Al, Ni, and Au, the second metal layer allowing diffusion of metal atoms into the semiconductor layer.

12. The metal oxide semiconductor capacitor of claim 10, wherein:
the first metal layer includes an alloy of Pt and Au or an alloy of Ti and at least one of Pt or Au;
the dielectric layer comprises SiO₂;
the semiconductor layer comprises at least one of Si or β-Ga₂O₃; and
the second metal layer comprises an alloy of Ti and Au or an alloy of Ti, Al, Ni and Au, the second metal layer allowing diffusion of metal atoms into the semiconductor layer.

13. A semiconductor transistor, comprising:
a gate; and
the diffusion barrier of claim 1.

14. The semiconductor transistor of claim 13, wherein the semiconductor transistor is a metal oxide semiconductor field-effect transistor, including:
the gate having an exterior, the exterior including at least one gate contact; and
a gate contact pad,
wherein the exterior, other than the at least one gate contact, is encompassed by the diffusion barrier of claim 1.

15. The metal oxide semiconductor field-effect transistor of claim 14, further including:
a source contact having a first source contact layer, a second source contact layer, and a third source contact layer;
a source contact pad having a single layer;
a drain contact having a first drain contact layer, a second drain contact layer, and a third drain contact layer;
a drain contact pad having a single layer;
a dielectric;
a semiconductor;
a passivation everywhere on the metal oxide semiconductor field-effect transistor except on the source contact pad, the drain contact pad, and the gate contact pad; and
an insulating substrate.

16. The metal oxide semiconductor field-effect transistor of claim 15, wherein:
the gate contact comprises:
a first metal sublayer having a first metal sublayer top and a first metal sublayer bottom, the first metal sublayer comprising at least one of Pt or Au;
a second metal sublayer having a second metal sublayer top and a second metal sublayer bottom, the second metal sublayer including at least one of Ti, Pt, or Au; and
a third metal sublayer having a third metal sublayer top and a third metal sublayer bottom, the third metal sublayer including at least one of Ti or Ni,
the second metal sublayer top being in contact with the first metal sublayer bottom, the third metal sublayer top being in contact with the second metal sublayer bottom, and the third metal sublayer bottom being in contact with the diffusion barrier top; or
the gate contact comprises an alloy of Pt and Au, or an alloy of at least one of Ti, Pt, or Au;
the first source contact layer and the first drain contact layer comprise Au;
the second source contact layer and the second drain contact layer each independently includes an alloy of Ti and Au, or an alloy of Ti, Al, Ni, and Au;
the third source contact layer and the third drain contact layer each independently includes a diffused alloy of Ti and Au, or a diffused alloy of Ti, Al, Ni and Au;
the dielectric layer comprises SiO₂; and
the semiconductor comprises at least one of Si or β-Ga₂O₃.

17. The semiconductor transistor of claim 13, wherein the semiconductor transistor is a GaN high electron mobility transistor (HEMT) and the gate includes the diffusion barrier of claim 1.

18. The GaN HEMT of claim 17, wherein the GaN HEMT includes:
a substrate;
a nucleation layer disposed over the substrate;
an isolating buffer disposed over the nucleation layer;
a GaN channel disposed over the isolating buffer;
an AlGaN barrier disposed over the GaN channel;
a GaN cap disposed over the AlGaN barrier;
the gate disposed over the GaN cap such that the diffusion barrier of claim 1 is disposed immediately adjacent to the GaN cap;
a metallic source; and
a metallic drain.

19. The semiconductor transistor of claim 13, wherein the semiconductor transistor has an operating temperature upper limit of at least 500° C.

20. An article selected from the group consisting of an aerospace vehicle, a re-entry vehicle, a hypersonic missile, a hypersonic lifting body, hypersonic plane, a hypersonic drone, an electric powered land vehicle, a gas drilling system, an oil drilling system, a nuclear reactor, and a gas turbine comprising the diffusion barrier of claim 1.

21. A process of making the diffusion barrier of claim 1, comprising depositing the diffusion barrier by physical vapor deposition.

22. The process of claim 21, wherein the physical vapor deposition includes a technique selected from the group consisting of sputtering, atomic layer deposition, electron beam evaporation, pulsed laser deposition, magnetron sputtering, and combinations thereof.
